(19) United States
(12) Patent Application Publication
(10) Pub. No.: US 2012/0266809 A1
(43) Pub. Date: Oct. 25, 2012

(54) INSULATION DEVICE OF SINGLE CRYSTAL GROWTH DEVICE AND SINGLE CRYSTAL GROWTH DEVICE INCLUDING THE SAME

(76) Inventors: Sang-Hoon Lee, Daegu (KR); Hyun-Jung Oh, Daegu (KR); Il-Soo Choi, Gyeongbuk (KR)

(21) Appl. No.: 13/542,590

(22) Filed: Jul. 5, 2012

(30) Foreign Application Priority Data
Jul. 21, 2010 (KR) PCT/KR2010/004775

(51) Int. Cl. C30B 15/00

(52) U.S. Cl. 117/217

(57) ABSTRACT

Provides are an insulation device of a single crystal growth device and a single crystal growth device including the same. The insulation device is installed inside a chamber of the single crystal growth device and the insulation device includes a plurality of insulation blocks that are spaced by a first distance.

### CROSS-REFERENCE TO RELATED APPLICATIONS

The present application claims priority to PCT application number PCT/KR2010/004775 filed Jul. 21, 2010, which is hereby incorporated by reference in its entirety

### BACKGROUND OF THE INVENTION

1. Technical Field

The present disclosure relates to an insulation device of a single crystal growth device and a single crystal growth device including the same.

2. Background Art

By growing single crystal silicon in an ingot form, a wafer is manufactured to be used for fabricating a semiconductor.

A typical manufacturing method for growing a silicon single crystal ingot (IG) includes a Czochralsk (CZ) method for growing crystal after dipping a single seed crystal in molten silicon and then slowly pulling it.

According to a related art, a heat insulator is designed to prevent heat generated from a heater from radiating to the external during a single crystal growth process. Through this design, an outer part of the heater is formed of a heat insulator having a low thermal conduction to avoid heat loss and the heat insulator has a thick thickness if possible.

Furthermore, although the single crystal growth device according to a related art controls heat release through a thickness of a heat insulator in order to prevent a heat generated from a heater from radiating toward the outside, there is a limitation in suppressing the heat release with only consideration in conduction except other factors such as convection and radiation.

### Technical Problem

Embodiments provide an insulation device of a single crystal growth device for effectively preventing heat flow and a single crystal growth device including the same.

### Solution to the Problem

In one embodiment, an insulation device installed inside a chamber of a single crystal growth device includes a plurality of insulation blocks that are spaced by a first distance.

In another embodiment, a single crystal growth device includes: a chamber including a heater; and an insulation device installed inside the chamber at one side of the heater, wherein the insulation device includes a plurality of insulation blocks spaced by a first distance.

### Advantageous Effects of Invention

According to an insulation device of a single crystal growth device and a single crystal growth device including the same, heat flow can be effectively blocked by using convention or radiation.

Moreover, according to an embodiment, a heater power value may be down to about 3 KW to about 8 KW based on 300 mm during a single crystal growth process, so that deterioration phenomenon of quartz crucible can be reduced, hot zone life time can be increased, and manufacturing cost can be curtailed.

Additionally, according to an embodiment, if heat power is high, because a temperature about a crucible is high, a melting state becomes unstable. However, the melting state may be stable by lowering the heat power.

Furthermore, if an insulation device of a single crystal growth device according to an embodiment is applied, silicon melting time is reduced during the same heat power operation compared to a related art single crystal growth device.

Besides, as reducing of a heater power value is significant during crystal growth of a large caliber such as about 450 mm, the reduced value may play an important role in a large caliber crystal growth technique.

### BRIEF DESCRIPTION OF THE DRAWINGS

FIG. 1 is a view of a single crystal growth device according to an embodiment.

FIG. 2 is a partial cross-sectional view illustrating an insulation device of a single crystal growth device according to a first embodiment.

FIG. 3 is a partial cross-sectional view illustrating an insulation device of a single crystal growth device according to a second embodiment.

FIG. 4 is a partial cross-sectional view illustrating an insulation device of a single crystal growth device according to a third embodiment.

FIG. 5 is a thermal distribution simulation result of an insulation device of a single crystal growth device according to a related art.

FIG. 6 is a thermal distribution simulation result of an insulation device of a single crystal growth device according to a first embodiment.

FIG. 7 is a thermal distribution simulation result of an insulation device of a single crystal growth device according to a second embodiment.

### BEST MODE FOR CARRYING OUT THE INVENTION

In the descriptions of embodiments, it will be understood that when a layer (or film), a region, a pattern, or a structure is referred to as being ‘on/above/over/upper’ substrate, each layer (or film), a region, a pad, or patterns, it can be directly on substrate each layer (or film), the region, the pad, or the patterns, or intervening layers may also be present. Further, it will be understood that when a layer is referred to as being ‘under/below/lower’ each layer (film), the region, the pattern, or the structure, it can be directly under another layer (film), another region, another pad, or another patterns, or one or more intervening layers may also be present. Therefore, meaning thereof should be judged according to the spirit of the present disclosure.

In the figures, a dimension of each of elements may be exaggerated for clarity of illustration, and the dimension of each of the elements may be different from an actual dimension of each of the elements. Not all elements illustrated in the drawings must be included and limited to the present disclosure, but the elements except essential features of the present disclosure may be added or deleted.

### Embodiment

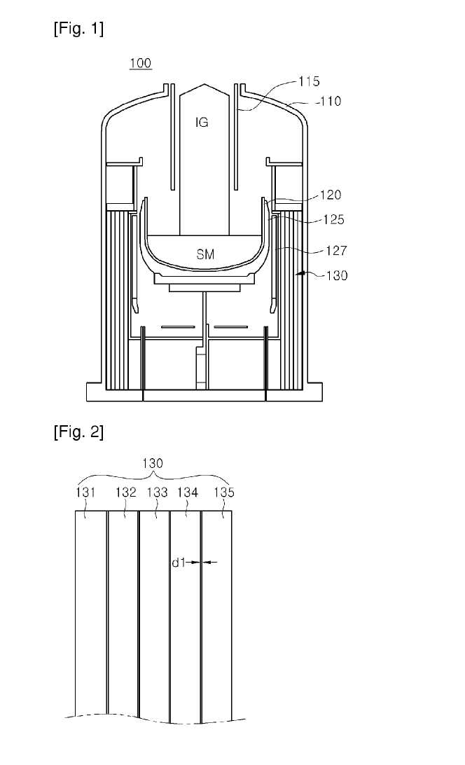

FIG. 1 is a view of a single crystal growth device 100 according to an embodiment.

The single crystal growth device 100 may include a chamber 110, a crucible 120, a heater 127, and a pulling means (not shown).

For example, the single crystal growth device 100 may include the chamber 110, the crucible 120 disposed in the chamber 110 and for receiving a silicon melting solution (SM), a heater 127 disposed in the chamber 110 and for heating the crucible 120, and a cooling pipe 115 for surrounding the single crystal ingot (IG).

The chamber 110 may provide a space where predetermined processes are performed to grow a single crystal ingot for a silicon wafer, which can be used for electronic components such as semiconductors.

The chamber 110 may include a growth chamber for receiving the crucible 120 and a full chamber on the growth chamber for growing a single crystal ingot (IG).

An insulation device 130 may be installed at the inner wall of the chamber 110 in order to prevent heat from radiating toward the sidewall of the chamber 110.

According to an embodiment, in order to control oxygen concentration during silicon single crystal growth, various factors such as pressure condition of rotation inside of the quartz crucible 120 may be controllable. For example, according to an embodiment, in order to control oxygen concentration, argon gas may be injected in the chamber 110 of the silicon single crystal growth device and then discharged through its bottom.

The crucible 120 may be equipped in the chamber 110 in order to contain silicon melting solution (SM) and may be formed of quartz material. A crucible supporter 125 formed of graphite may be equipped at the external of the crucible 120 to support the crucible 120. The crucible supporter 125 may be fixed on a rotation axis (not shown). The rotation axis may be rotated by a driving means (not shown) and thus allows the crucible 120 to rotate, raise or lower the crucible 120, thereby maintaining solid-liquid interface to be the same height.

The heater 127 may be equipped in the chamber 110 to heat the crucible 120. For example, the heater 127 may have a cylindrical form that surrounds the crucible supporter 125. The heater 127 may melt poly crystal silicon lump of high purity loaded in the crucible 120 to form it as a silicon melting solution (SM).

A manufacturing method for growing a silicon single crystal ingot (IG) according to an embodiment includes a Czochralsk (CZ) method for growing crystal after dipping a single seed crystal in molten silicon and then slowly pulling it.

According to this method, first of all, following a necking process that grows a thin and long crystal from a seed crystal, a shouldering process that grows the crystal in a diameter direction to form a target diameter is performed and then a body growing process that grows the crystal to have a predetermined diameter is performed. Then, after the growing of the crystal body to have a predetermined length, a tailing process that slowly reduces the diameter of the crystal in order to separate it from the melting silicon is performed. After that, growing of the single crystal ingot (IG) may be completed.

FIG. 1 is a view illustrating a body growing process among single crystal ingot (IG) growth processes.

FIG. 2 is a partial cross-sectional view of an insulation device in a single crystal growth device according to a first embodiment.

The insulation device 130 of the single crystal growth device according to the first embodiment may include a plurality of insulation blocks 131 to 135, which are respectively formed being spaced by a first predetermined distance d1.

According to an embodiment, by forming of an insulation of the insulation device 130 with the plurality of separate insulation blocks 131 to 135 not with one block, a power value of a heater may be reduced through insulation effect related to radiation.

Referring to FIG. 2, the number of insulation blocks is 5 but is not limited thereto and thus more than two insulation blocks also is possible.

Moreover, according to an embodiment, by setting a spaced distance between the insulation blocks 131 to 135 as the first distance d1 of about 1 mm to about 5 mm, a power value of a heater may be reduced through insulation effect related to radiation.

According to an embodiment, the first distance d1, the spaced distance between the insulation blocks 131 to 135, is not necessarily be the same and may vary in a range of about 1 mm to about 5 mm.

TABLE 1

| | Distance between insulation blocks | | | |
|---|---|---|---|---|
| | 0 mm | 1 mm | 3 mm | 5 mm |
| Heater power value | 97.9 KW | 97.1 KW | 97.6 KW | 97.8 KW |

Table 1 is a heater power value according to a first distance between insulation blocks.

According to the first embodiment, a power value of a heater may be reduced by about 1 KW through insulation effect related to radiation, with a plurality of insulation blocks and a spaced distance of about 1 mm to about 5 mm between the insulation blocks.

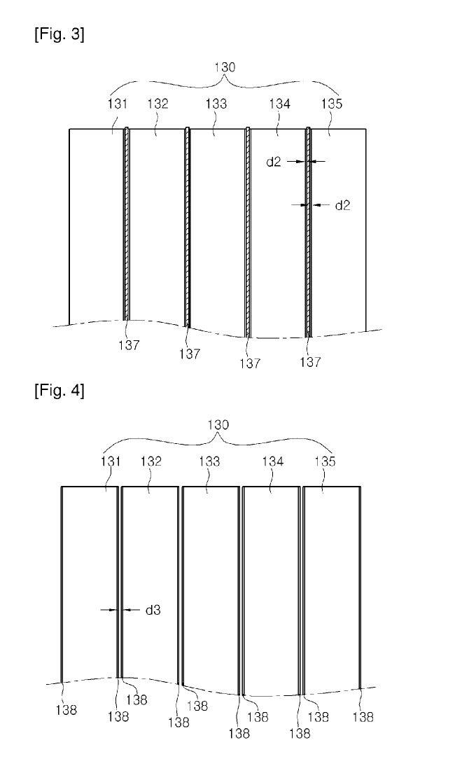

FIG. 3 is a partial cross-sectional view of an insulation device of a single crystal growth device according to a second embodiment.

The second embodiment may employ technical features of the first embodiment.

The insulation device of the single crystal growth device according to the second embodiment may further include a first insulation layer 137 between the insulation blocks 131, 132, 133, 134, and 135.

For example, according to an embodiment, a first insulation layer 137 having a lower emissivity than the insulation block may be interposed between the plurality of insulation blocks in consideration of a radiation effect.

For example, if a material having emissivity of less than 0.8 is added as the first insulation layer 137, insulation effect is increased, thereby reducing a heat power value.

According to an embodiment, steel having a lower emissivity of about 0.45 (compared to graphite having an emissivity of about 0.8) may be adopted as a material of the first insulation layer 137 but embodiments are not limited thereto.

According to an embodiment, a second distance d2 between the insulation block and the first insulation layer 137 may be between about 1 mm and about 10 mm.

TABLE 2

| | Distance between insulation block | | |
|---|---|---|---|
| | and first insulation layer | | |
| | 1 mm | 5 mm | 10 mm |
| Heat power value | 95.82 KW | 96.62 KW | 97.35 KW |

Table 2 is a heater power value according to the second distance d2 between the insulation block and the first insulation layer.

According to the second embodiment, if a material of low emissivity as the first insulation layer 137 is additionally inserted between insulation blocks, insulation effect is increased, such that it is confirmed that a heater power value is drastically reduced.

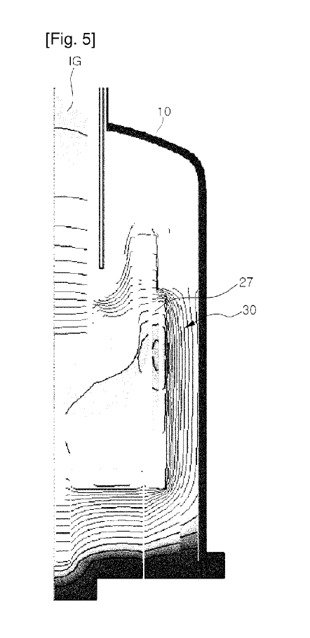

FIG. 4 is a partial cross sectional view of an insulation device of a single crystal growth device according to a third embodiment.

The third embodiment may adopt technical features of the first and second embodiments.

The third embodiment may include a coated second insulation layer 138 on the outer walls of the insulation blocks 131 to 135.

The second insulation layer 138 may have a lower emissivity than the insulation block and a third distance d3 between the second insulation layers 138 may be between about 1 mm and about 10 mm.

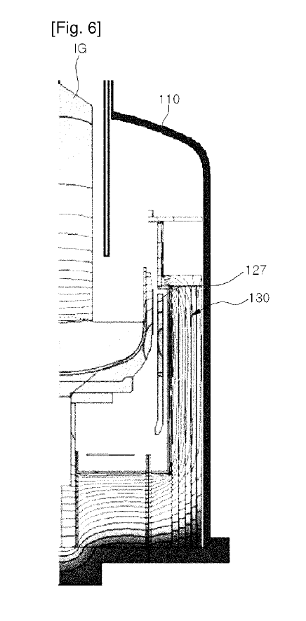

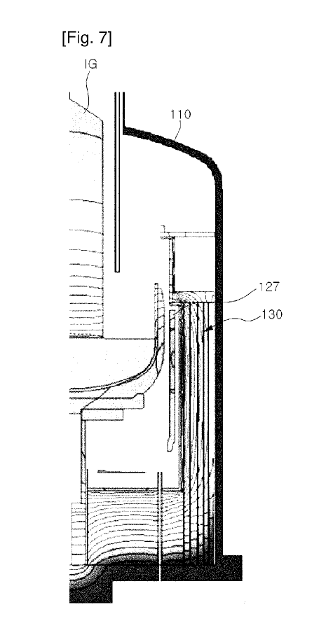

FIG. 5 is a thermal distribution simulation result of a single crystal growth device according to a related art. FIG. 6 is a thermal distribution simulation result of a single crystal growth device according to the first embodiment. FIG. 7 is a thermal distribution simulation result of a single crystal growth device according to the second embodiment.

Referring to FIG. 5, according to a related art, a chamber 10, a heater 27, and a heat insulator 30 of a single block are included. Referring to FIG. 6, according to the first embodiment, five insulation blocks are configured by about 1 mm interval.

According to the first embodiment, an insulation block is in plurality and a spaced distance between the insulation blocks is between about 1 mm and about 10 mm. Therefore, a power value of a heater may be reduced by about 1 KW through insulation effect related to radiation.

In FIG. 7, a material of a low emissivity as a first insulation layer is inserted between insulation blocks to increase insulation effect. For example, the first insulation layer 137 of a steel material having an about 1 mm thickness is inserted between insulation blocks of graphite, being spaced about 1 mm from the insulation block.

According to the second embodiment, if a material of a low emissivity as the first insulation layer 137 is inserted between insulation blocks, insulation effect is increased such that a heater power value is reduced by more than about 3 KW.

According to an insulation device of a single crystal growth device and a single crystal growth device including the same, heat flow can be effectively blocked through convection and radiation.

Moreover, a heater power value may be down to about 3 KW to about 8 KW based on 300 mm during a single crystal growth process, so that deterioration phenomenon of quartz crucible can be reduced,

Additionally, according to an embodiment, if heat power is high, because a temperature about a crucible is high, a melting state becomes unstable. However, the melting state may be stable by lowering the heat power.

Furthermore, if an insulation device of a single crystal growth device according to an embodiment is applied, silicon melting time is reduced during the same heat power operation compared to a related art single crystal growth device.

Besides, as reducing of a heater power value is significant during crystal growth of a large caliber such as about 450 mm, the reduced value may play an important role in a large caliber crystal growth technique.

Although embodiments have been described with reference to a number of illustrative embodiments thereof, it should be understood that numerous other modifications and embodiments can be devised by those skilled in the art that will fall within the spirit and scope of the principles of this disclosure.

More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

### INDUSTRIAL APPLICABILITY

According to an embodiment, a heater power value may be down to about 3 KW to about 8 KW based on a silicon ingot diameter of about 300 mm during a single crystal growth process, but embodiments are not limited thereto.

For example, a silicon ingot of a large caliber such as about 450 mm may be applied during crystal growth, in order to reduce a heater power value.

What is claimed is:

1. An insulation device installed inside a chamber of a single crystal growth device, the insulation device comprising:
a plurality of insulation blocks that are spaced by a first distance.

2. The insulation device according to claim 1, wherein the first distance between the insulation blocks is between about 1 mm and about 5 mm.

3. The insulation device according to claim 1, further comprising a first insulation layer between the insulation blocks.

4. The insulation device according to claim 3, wherein a second distance between the insulation block and the first insulation layer is between about 1 mm and about 10 mm.

5. The insulation device according to claim 4, wherein the first insulation layer has a lower emissivity than the insulation block.

6. The insulation device according to claim 5, wherein the first insulation layer has an emissivity of less than about 0.8.

7. The insulation device according to claim 1, further comprising a second insulation layer coated on an outer wall of the insulation block.

8. The insulation device according to claim 7, wherein the second insulation layer has a lower emissivity than the insulation block.

9. A single crystal growth device comprising:
a chamber including a heater; and
an insulation device installed inside the chamber at one side of the heater, wherein the insulation device includes a plurality of insulation blocks spaced by a first distance.

10. The single crystal growth device according to claim 9, wherein the first distance between the insulation blocks of the insulation device is between about 1 mm and about 10 mm.

11. The single crystal growth device according to claim 9, wherein the insulation device further comprises a first insulation layer between the insulation blocks.

12. The single crystal growth device according to claim 11, wherein a second distance between the insulation block and the first insulation layer is between about 1 mm and about 10 mm.

13. The single crystal growth device according to claim 11, wherein the first insulation layer has a lower emissivity than the insulation block.

14. The single crystal growth device according to claim 13, wherein the first insulation layer has an emissivity of less than about 0.8.

15. The single crystal growth device according to claim 9, further comprising a second insulation layer coated on an outer wall of the insulation block.

16. The single crystal growth device according to claim 15, wherein the second insulation layer has a lower emissivity than the insulation block.
